(19) United States
(12) Patent Application Publication
(10) Pub. No.: US 2004/0190377 A1
(43) Pub. Date: Sep. 30, 2004

(54) Method and means for isolating elements of a sensor array

(76) Inventors: Robert Stephen Lewandowski, Amsterdam, NY (US); Lowell Scott Smith, Schenectady, NY (US); Charles Edward Baumgartner, Schenectady, NY (US); David Martin Mills, Niskayuna, NY (US); Douglas Glenn Wildes, Ballston Lake, NY (US); Rayette Ann Fisher, Niskayuna, NY (US); George Charles Sogoian, Glenville, NY (US)

Correspondence Address: Dennis M. Flaherty, Esq., Ostrager Chong & Flaherty LLP, 30th Floor, 825 Third Avenue, New York, NY, 10022-7519, US

(21) Appl. No.: 10/814,956

(22) Filed: Mar. 31, 2004

Related U.S. Application Data
(63) Continuation-in-part of application No. 10/383,990, filed on Mar. 6, 2003.

(51) Int. Cl. H01L 21/00

(52) U.S. Cl. 367/174

(57) ABSTRACT

A device comprising an array of sensors built on or in a substrate with a semiconducting surface and means for isolating each sensor element from its neighbors. In the case where the sensors are ultrasonic transducer elements, acoustic isolation is provided in the form of trenches between neighboring transducer elements to reduce acoustic crosstalk. The trenches may be filled with acoustically attenuative material. Electrical isolation in the form of semiconductive junctions is provided between neighboring transducer elements to reduce electrical crosstalk. In one example, back-to-back pn junction diodes are formed by ion implantation in zones located between neighboring transducer elements. These types of isolation can be employed alone or together.

### RELATED PATENT APPLICATION

This application is a continuation-in-part and claims priority from U.S. patent application Ser. No. 10/383,990 filed on Mar. 6, 2003 and entitled “Mosaic Arrays Using Micromachined Ultrasound Transducers”.

### BACKGROUND OF THE INVENTION

This invention generally relates to sensor arrays (e.g., optical, thermal, pressure, ultrasonic). In particular, the invention relates to micromachined ultrasonic transducers (MUTs). One specific application for MUTs is in medical diagnostic ultrasound imaging systems. Another specific example is for non-destructive evaluation (NDE) of materials, such as castings, forgings, or pipelines.

Conventional ultrasound imaging transducers generate acoustic energy via a piezoelectric effect in which electrical energy is converted into acoustic energy using a poled piezoelectric ceramic material. The acoustic energy that is transmitted in the forward direction, which is in the direction of the patient being scanned, is coupled to the patient through one or more acoustic matching layers. However, the acoustic energy transmitted in the direction away from the patient being scanned is typically absorbed in and/or scattered in an acoustic backing material located on the backside of the transducer array. This prevents the acoustic energy from being reflected from structures or interfaces behind the transducer and back into the piezoelectric material, thereby reducing the quality of the acoustic image obtained from reflection within the patient. Numerous compositions for the acoustic backing material are known. For example, the acoustic backing material may consist of a composite of metal particles (e.g., tungsten) in an attenuating soft material such as rubber, epoxy or plastic. Other acoustic backing material compositions may also be used.

The ultrasonic transducers used for medical diagnostic imaging have broad bandwidth and high sensitivity to low-level ultrasonic signals, which characteristics enable the production of high-quality images. Piezoelectric materials that satisfy these criteria and have been conventionally used to make ultrasonic transducers include lead zirconate titanate (PZT) ceramic and polyvinylidene fluoride. However, PZT transducers require ceramic manufacturing processes that are different from the processing technologies used to manufacture other parts of an ultrasound system, such as semiconductor components. It is desirable that ultrasonic transducers be manufactured using the same processes used to fabricate the semiconductor components.

Recently semiconductor processes have been used to manufacture ultrasonic transducers of a type known as micromachined ultrasonic transducers (MUTs), which may be of the capacitive (cMUT) or piezoelectric (PMUT) variety. cMUTs are tiny diaphragm-like devices with electrodes that convert the sound vibration of a received ultrasound signal into a modulated capacitance. For transmission the capacitive charge is modulated to vibrate the diaphragm of the device and thereby transmit a sound wave. pMUTs are similar except that the diaphragm is bimorphic, consisting of a piezoelectric and an inert material like silicon nitride or silicon.

One advantage of MUTs is that they can be made using semiconductor fabrication processes, such as microfabrication processes grouped under the heading “micromachining”. As explained in U.S. Pat. No. 6,359,367:

Micromachining is the formation of microscopic structures using a combination or subset of (A) Patterning tools (generally lithography such as projection-aligners or wafer-steppers), and (B) Deposition tools such as PVD (physical vapor deposition), CVD (chemical vapor deposition), LPCVD (low-pressure chemical vapor deposition), PECVD (plasma chemical vapor deposition), and (C) Etching tools such as wet-chemical etching, plasma-etching, ion-milling, sputter-etching or laser-etching. Micromachining is typically performed on substrates or wafers made of silicon, glass, sapphire or ceramic. Such substrates or wafers are generally very flat and smooth and have lateral dimensions in inches. They are usually processed as groups in cassettes as they travel from process tool to process tool. Each substrate can advantageously (but not necessarily) incorporate numerous copies of the product. There are two generic types of micromachining . . . 1) Bulk micromachining wherein the wafer or substrate has large portions of its thickness sculptured, and 2) Surface micromachining wherein the sculpturing is generally limited to the surface, and particularly to thin deposited films on the surface. The micromachining definition used herein includes the use of conventional or known micromachinable materials including silicon, sapphire, glass materials of all types, polymers (such as polyimide), polysilicon, silicon nitride, silicon oxynitride, thin film metals such as aluminum alloys, copper alloys and tungsten, spin-on-glasses (SOGs), implantable or diffused dopants and grown films such as silicon oxides and nitrides.

The same definition of micromachining is adopted herein. The systems resulting from such micromachining processes are typically referred to as “micromachined electromechanical systems (MEMS).

Acoustic energy generated using a capacitive micromachined ultrasonic transducer device does not rely on a piezoelectric material to generate ultrasonic energy. Rather, the basic structure of a cMUT cell is that of a conductive membrane or diaphragm suspended above a conductive electrode by a small gap. When a voltage is applied between the membrane and the electrode, Coulombic forces attract the membrane to the electrode. If the applied voltage varies in time, so too will the membrane position, generating acoustic energy that radiates from the face of the device as the membrane moves in position. While the acoustic energy is generated primarily in the forward, or patient, direction, some fraction of the acoustic energy will be propagated into the cMUT supporting structure. This structure is commonly a heavily doped silicon, and hence semiconductive, wafer.

The cMUT device is typically built with multiple membranes per transducer element. A complete transducer probe used for medical imaging, non-destructive evaluation or some other imaging device comprises multiple transducer elements arranged in a row or rows to form an array, each element comprising a plurality of cMUT cells having their electrodes electrically connected together. Each element of the array needs to act independently from its neighbors. Since the array of transducer elements is built on a common substrate, the problem exists that there will be both electrical and mechanical interference between neighboring elements (i.e., crosstalk).

There is a need to provide isolation between the transducer elements of MUT (cMUT and pMUT) devices.

### BRIEF DESCRIPTION OF THE INVENTION

The present invention is directed to devices comprising an array of sensors built on or in a substrate and means for isolating each sensor element from its neighbors. In the case of semiconducting wafers, the semiconducting surface is usually one face of the semiconducting wafer, but it can also be a film of semiconductor on an insulating substrate. The invention is also directed to methods of manufacturing such devices. In accordance with some disclosed embodiments, acoustic isolation is provided between neighboring sensor elements to reduce acoustic crosstalk. In accordance with other disclosed embodiments, electrical isolation is provided between neighboring sensor elements to reduce electrical crosstalk. These types of isolation can be employed alone or together in a sensor device. The sensors may be optical, thermal or pressure sensors or ultrasonic transducers.

One aspect of the invention is a sensor device comprising: a multiplicity of sensor elements arranged at a front surface of a substrate, each of the sensor elements being in contact with material of the substrate; and a multiplicity of barriers arranged in the material of the substrate to reduce the coupling of a form of energy between any of the sensor elements, each barrier posing an obstacle to the propagation of the form of energy impinging thereon.

Another aspect of the invention is a method of manufacturing a sensor device comprising the following steps: (a) micromachining an array of sensor elements in or on a substrate; and (b) forming a multiplicity of barriers in the material of the substrate to reduce the coupling of a form of energy between any of the sensor elements, each barrier posing an obstacle to the propagation of the form of energy impinging thereon.

A further aspect of the invention is an ultrasonic transducer device comprising: a multiplicity of ultrasonic transducer elements arranged at a front surface of a substrate, each of the transducer elements comprising a respective group of ultrasonic transducer cells electrically connected together and acoustically coupled to the substrate; and a multiplicity of trenches in the material of the substrate, the trenches being disposed in areas between the transducer elements, and the trenches obstructing the propagation of acoustic wave energy therethrough.

Yet another aspect of the invention is a sensor device comprising: a multiplicity of sensor elements arranged at a front surface of a substrate, each of the sensor elements being in contact with material of the substrate; and a multiplicity of zones of dopant implantation in the material of the substrate, the zones being disposed in areas between the sensor elements, and the zones obstructing the flow of electric current therethrough.

A further aspect of the invention is a method of manufacturing a sensor device comprising the following steps: (a) micromachining an array of sensors on one side of a substrate; (b) attaching the one side or the other side of the substrate to a first supporting structure; and (c) forming a multiplicity of trenches in the material on the side of the substrate not attached to the supporting structure, wherein the trenches are located in areas between the sensor elements.

Other aspects of the invention are disclosed and claimed below.

### BRIEF DESCRIPTION OF THE DRAWINGS

FIG. 1 is a drawing showing a cross-sectional view of a typical cMUT cell.

FIG. 2 is a drawing showing an isometric view of the cMUT cell shown in FIG. 1.

FIG. 3 is a drawing showing a side view of a cMUT device and associated electrical connections supported by a layer of acoustic backing material.

FIG. 4 is a drawing showing an isometric view of a grouping of cMUT cells that are electrically connected together on top of a substrate and acoustic backing material.

FIG. 5 is a drawing showing an isometric view of a substrate that has been micromachined to form a row of spaced transducer elements, each element comprising a multiplicity of electrically connected cMUT cells.

FIG. 6 is a drawing showing two different types of acoustic isolation trenches that can be formed in the micromachined substrate of FIG. 1 in accordance with respective embodiments of the invention.

FIG. 7 is a drawing showing four different types of acoustic isolation trenches that can be formed in the micromachined substrate of FIG. 1 in accordance with respective embodiments of the invention.

FIG. 8 is a drawing showing the formation of acoustic isolation trenches on the back of a micromachined substrate in accordance with yet another embodiment of the invention.

FIGS. 9 and 10 are drawings respectively showing cMUT elements built on semiconductive substrates wherein the substrate is doped to provide electrical isolation between transducer elements in accordance with further embodiments of the invention.

FIG. 11 is a drawing showing a pair of cMUT cells built on an n-type semiconductive substrate wherein the walls supporting the membranes are made of p-type semiconductive material for providing electrical isolation in accordance with yet another embodiment of the invention.

Reference will now be made to the drawings in which similar elements in different drawings bear the same reference numerals.

### DETAILED DESCRIPTION OF THE INVENTION

For the purpose of illustration, various embodiments of the invention will be described that belong to the class of capacitive micromachined ultrasonic transducers (cMUTs). However, it should be understood that the aspects of the invention disclosed herein are not limited to the structure or manufacture of cMUTs, but rather also apply to the structure or manufacture of other types of sensor arrays on a substrate. Nor is the invention limited to substrates made of semiconductive material.

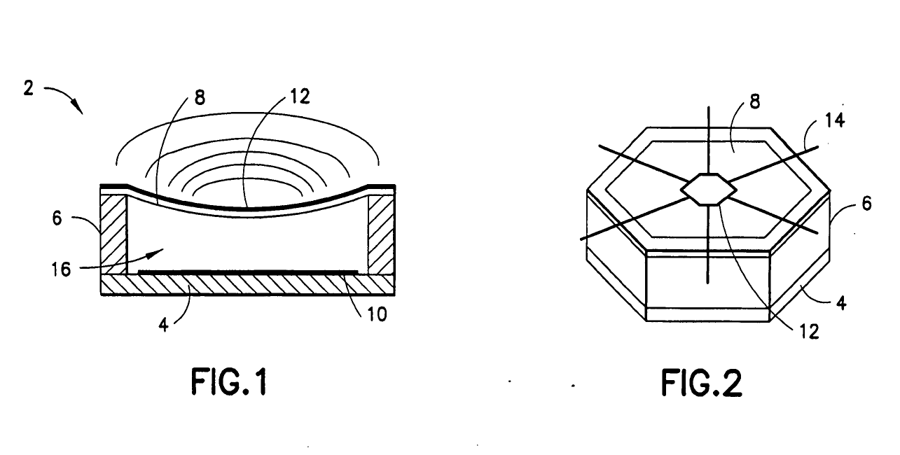

Referring to FIG. 1, a typical cMUT transducer cell 2 is shown in cross section. An array of such cMUT transducer cells is typically fabricated on a substrate 4, such as a heavily doped silicon (hence, semiconductive) wafer. For each cMUT transducer cell, a thin membrane or diaphragm 8, which may be made of silicon or silicon nitride, is suspended above the substrate 4. The membrane 8 is supported on its periphery by an insulating support 6, which may be made of silicon oxide, silicon nitride, or the substrate material. The cavity 16 between the membrane 8 and the substrate 4 may be air- or gas-filled or wholly or partially evacuated. A film or layer of conductive material, such as aluminum alloy or other suitable conductive material, forms an electrode 12 on the membrane 8, and another film or layer made of conductive material forms an electrode 10 on the substrate 4. Alternatively, the bottom electrode can be formed by appropriate doping of the substrate. As shown in the FIG. 1, the electrode 12 is on top of the membrane, but it could also be embedded in the membrane or on the bottom side of the membrane.

The two electrodes 10 and 12, separated by the cavity 16, form a capacitance. When an impinging acoustic signal causes the membrane 8 to vibrate, the variation in the capacitance can be detected using associated electronics (not shown in FIG. 1), thereby transducing the acoustic signal into an electrical signal. Conversely, an AC signal applied to one of the electrodes will modulate the charge on the electrode, which in turn causes a modulation in the capacitive force between the electrodes, the latter causing the diaphragm to move and thereby transmit an acoustic signal.

Due to the micron-size dimensions of a typical cMUT, numerous cMUT cells are typically fabricated in close proximity to form a single transducer element. The individual cells can have round, rectangular, hexagonal, or other peripheral shapes. Of the simple shapes that achieve close packing, hexagonal shapes are closest to circular and therefore have the simplest resonant modes. A cMUT cell having a hexagonal shape is shown in FIG. 2. Hexagonal shapes provide dense packing of the cMUT cells of a transducer element. The cMUT cells can have different dimensions so that the transducer element will have composite characteristics of the different cell sizes, giving the transducer a more broadband characteristic. The “spokes” 14 shown in FIG. 2, which electrically connect one cell to another, are part of the patterned electrode referenced as item 12 in FIG. 1. The electrode 12 can be patterned for optimal acoustic performance and can be positioned on the bottom of membrane 8.

The cMUT device may further comprise a layer of acoustically attenuative material, referred to herein as “acoustic backing”, acoustically coupled to the rear face of the substrate. The acoustic backing layer has sufficient stiffness to provide structural support for a very thin substrate. Such an acoustic backing layer may be joined directly to the rear face of the substrate, e.g., using a layer of epoxy that is thin enough to be substantially acoustically transparent, or may be laminated to the substrate with intervening layers. Alternatively, the acoustic backing could be a castable or moldable composition that possesses sufficient acoustic impedance. In one embodiment, the intervening layer is made of acoustic impedance matching material having an acoustic impedance that lies between the acoustic impedance of the silicon substrate and the acoustic impedance of the acoustically attenuative material. In another embodiment, the intervening layer is a flexible printed circuit board (“flex circuit”) having electrically conductive pads that connect to electrically conductive vias in the substrate. Preferably the acoustic backing material has attenuation properties such that waves that propagate laterally in the substrate are absorbed to a degree that reduces cross-talk between transducer elements.

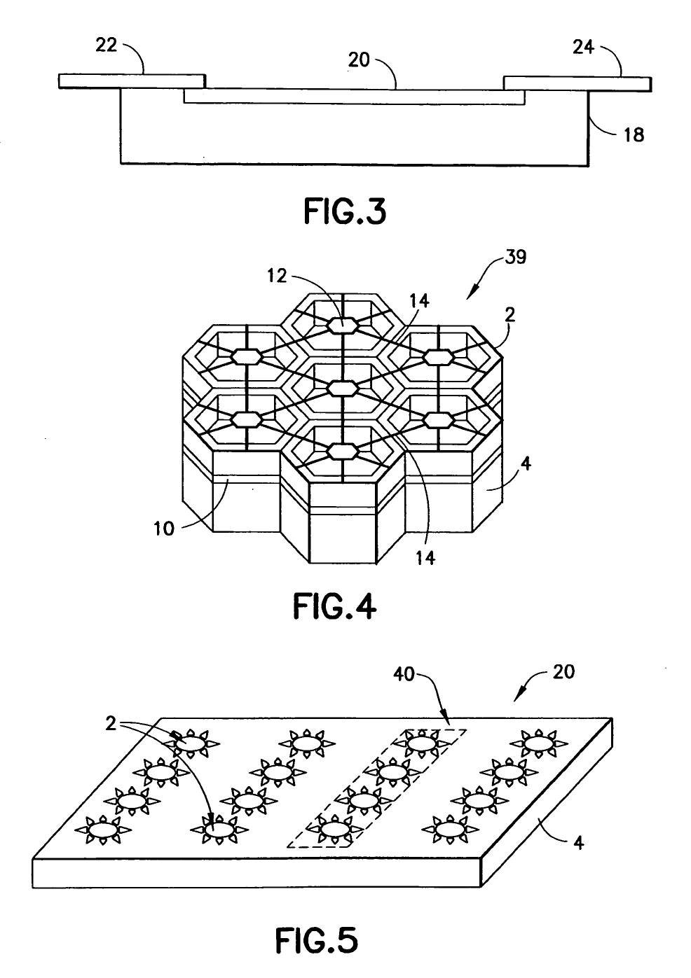

FIG. 3 shows a side view of a cMUT device 20 connected to appropriate electronics (not shown) via electrical connections (e.g., flex circuits) 22 and 24. [As used herein, the term “cMUT device” means a structure comprising a substrate and a multiplicity of cMUT cells supported by that substrate.] In the depicted embodiment, the cMUT device 20 is seated in a formed well in a body of acoustic backing material 18. The top of the substrate lies generally flush with the top of those portions of the acoustic backing that extend beyond the footprint of the substrate, the distal edges of the flexible electrical connections 22 and 24 overlapping respective edges of the substrate, and adjoining portions of the flexible electrical connections 22 and 24 overlapping and joined to respective portions of the acoustic backing layer. As seen in FIG. 3, the acoustic backing layer 18 supports the cMUT device 20 as well as the flexible electrical connections 22 and 24. The acoustic backing 18 may be laminated directly to the cMUT device 20 or, as previously mentioned, an intervening acoustic impedance matching layer may be included in the laminated stack.

The micromachined ultrasound transducer array can be built on the surface of a substrate or can be sculpted by removing material from the substrate. The array may comprise one or more rows of transducer elements, or the transducer elements may be organized in a two-dimensional arrangement that does not have rows, such as in a so-called “mosaic array” in which cMUT cells or elements are tessellated on the substrates as disclosed in U.S. patent application Ser. No. 10/383,990.

Each transducer element in a typical cMUT device is built with multiple cMUT cells. For the purpose of illustration, FIG. 4 shows a “daisy” transducer element made up of seven hexagonal cMUT cells 2: a central cell surrounded by a ring of six cells, each cell in the ring being contiguous with a respective side of the central cell and the adjoining cells in the ring. The top electrodes 12 of each cell 2 are electrically connected together (the connections are not switchably disconnectable). In the case of a hexagonal array, six conductors 14 (shown in both FIGS. 2 and 4) radiate outward from the top electrode 12 and are respectively connected to the top electrodes of the neighboring cMUT cells (except in the case of cells on the periphery, which connect to three, not six, other cells). Similarly, the bottom electrodes 10 of each cell 2 are electrically connected together, forming a seven-times-larger capacitive transducer element 39.

The arrangement of cells seen in FIG. 4 can be extended in one direction to form a long, generally rectangular transducer element 40. These rectangular transducer elements can be arranged in a row to form a linear array. Such a cMUT device 20 is generally represented in FIG. 5, with the caveat that each rectangular transducer element 40 is depicted, for ease of drawing, as having a single column of cMUT cells, but it should be appreciated that in fact each element comprises multiple columns of cMUT cells.

Each transducer element of the array needs to act independently from its neighbors. Since, as shown in FIG. 5, the array is built on a common substrate 4, the problem exists that there can be both electrical and mechanical interference between neighboring elements (i.e., crosstalk). The present invention provides the isolation needed between elements.

In accordance with a first class of embodiments of the invention, isolation is provided by removing all or part of the substrate material between neighboring transducer elements. This can be accomplished by using a wafer dicing saw, a laser, wet etch techniques, reactive ion etching (RIE), or deep RIE.

One method of producing an isolation trench would be to first mount the substrate carrying the cMUT cells or elements to a backing material, as seen in FIG. 3. FIG. 6 shows a substrate 4 laminated to a backing layer 18 made of acoustically attenuative material. A wafer dicing saw (not shown) can be used to cut through the substrate 4 and part way into the backing material 18, thereby forming a multiplicity of spaced apart, mutually parallel isolation trenches or channels like isolation trench 26 seen in FIG. 6. Depending on the operating frequency of the cMUT device, it may not be necessary to cut completely through the substrate 4. Instead isolation trenches or channels 28 having a depth less than the full thickness of the substrate 4 could be formed, as is also shown in FIG. 6. It should be appreciated that trenches of different depth are shown in the same drawing for the sake of economy, and that typically the isolation trenches in a particular cMUT wafer would have the same depth.

In the case where the isolation trenches pass through the entire thickness of the substrate 4 and into the backing layer 18, the backing material will provide the mechanical support for each transducer element. Since the backing material damps the acoustic energy, crosstalk through the backing layer 18 will be considerably less than through the substrate 4.

Regardless of their depth, the isolation trenches are located in the open spaces between neighboring transducer elements. FIG. 6 shows one row of transducer elements, each transducer element comprising a multiplicity of cMUT cells 2. In the case of a linear array having one row of elements, mutually parallel isolation trenches would be disposed in the open spaces between adjacent elements. If the array comprises two or more rows, then isolation trenches would also be placed in the open spaces between rows, intersecting the trenches within each row to form an interconnected network of isolation trenches. In this case, the isolation trenches between rows would be parallel to each other and perpendicular to the isolation trenches in each row. If the elements in each row are aligned to form columns, then the intersecting isolation trenches will form a lattice or grid.

After the transducer elements have been acoustically isolated, the isolation trenches between the transducer elements can be filled with an acoustically absorbing material such as silicone rubber. In the case where a lens will be adhered to the face of the cMUT device, to either focus the acoustic wave and/or protect the face of the device, filling the isolation trenches with the lens adhesive would improve the adhesion of the lens to the cMUT device. The filling of the trenches between the elements would also add mechanical support to the elements.

It may also be determined that the configuration of the trench should have an optimum shape. Referring to FIG. 7, the isolation trench does not need to have a profile with a right-angled bottom (see trench 30), but instead the profile could be in the shape of a “V” (see trench 32) or “U” (not shown). The trenches 34 and 36 in FIG. 6 show other profiles. The profile of trench 34 has parallel side walls and a generally parabolic bottom profile, while trench 36 has parallel side walls and a V-shaped bottom profile. It should be apparent that all of the isolation trenches formed in the substrate 4 will typically have profiles of the same shape, and that the different shapes shown in FIG. 6 are grouped together in one substrate to minimize the number of drawings needed.

The use of a dicing saw is an effective way to remove substrate material located between the transducer elements as long as the resulting kerfs or trenches have a straight-line geometry. If material needs to be removed along lines that are not straight, other methods such as laser cutting, wet etch techniques or RIE are more applicable. An example of this would be a device that was built in a circular shape (e.g., an annular array). This circular transducer array has elements that form concentric annular rings and therefore require circular isolation patterns. This geometry allows for a point focus of the acoustic energy.

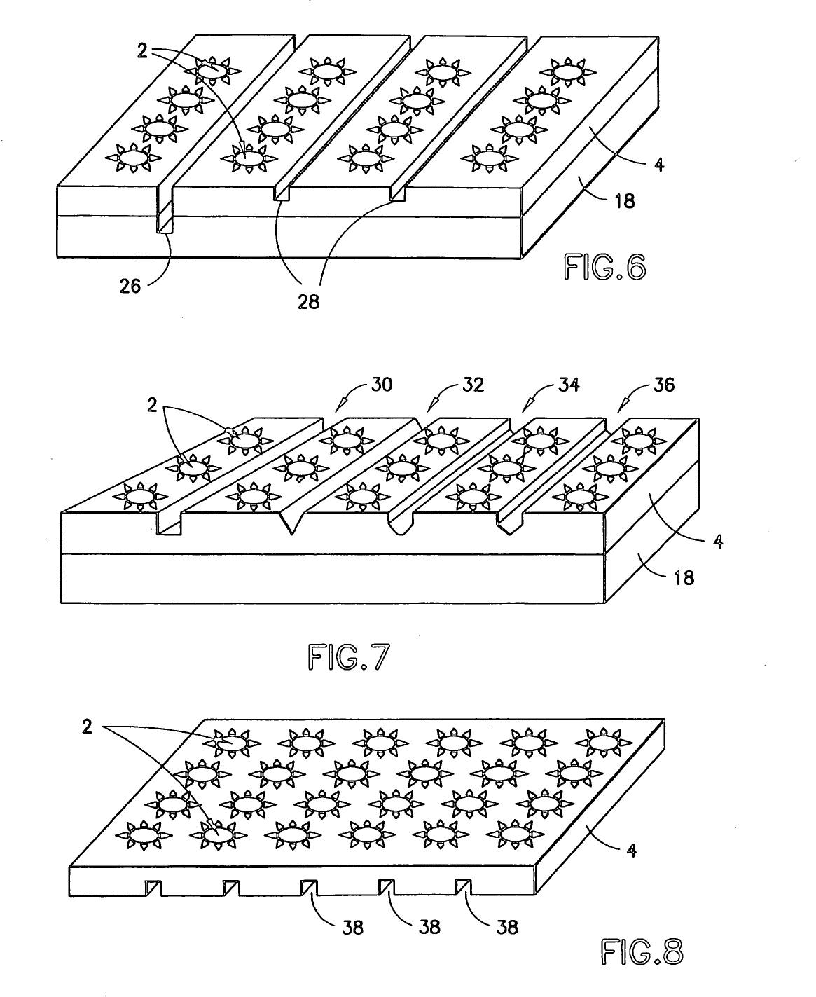

It is within the scope of the present invention to perform any of the above-described acoustic isolation techniques on either side of the substrate. If material were removed from the back of the device, opposite the cMUT cells as shown in FIG. 8, a larger active area can be obtained so long as the isolation trenches 38 do not extend through the entire thickness of the substrate 4. In this case the trenches can be made to occupy the area directly below the cMUT cells or elements.

The cMUT device needs to be supported on the front (i.e., the cMUT cell side) in order to provide backside isolation. However, since the cMUT device can be easily damaged, dicing tapes cannot be used. Tape that is stuck to the suspended membranes might pull them off. In accordance with one embodiment of the invention, during the provision of acoustic isolation on the back, the cMUT device is supported by a low-temperature mounting wax applied on the front of the device, in contact with the fragile cMUT membranes. After the isolation process has been completed and the cMUT device has been cleaned of debris from the dicing operation, the cMUT would need to be supported before removing the. mounting wax. This support could be the acoustically attenuative backing previously described. After the cMUT device has been mounted to the support, it would be heated to melt the mounting wax. Using the appropriate solvents for the mounting wax, the cMUT device would be cleaned of the wax. An alternate supporting scheme would be to only support the cMUT outside the active region and avoid bonding directly to the membranes.

With any of the above-described methods of providing isolation of the cMUT elements, there is the possibility of damage such as micro-cracks, which could propagate into the active cMUT cells. This could allow infiltration of a modestly conducting liquid to short the signal and ground electrodes. Another aspect of the present invention would provide a preventive measure by applying a conformal coating, such as sputtered or vapor-deposited silica, silicon nitride, alumina, or other insulating inorganics, to seal over such defects. A vapor-deposition coating process is capable of producing a pinhole free coating of outstanding conformity and thickness uniformity and is performed under vacuum.

The coating process would be carried out as follows. After the removal of the material from between the cMUT elements to form the isolation trenches, the cMUT cells would be cleaned to remove any residues left thereon. Then the cMUT device would be dried at an elevated temperature in a vacuum. After the cMUT device had been dried, it would be placed into a sputtering or vapor coating machine and coated with several microns of the selected material. Even though such coatings are very conformal, the micro-cracks, if sufficiently small, would be sealed over and the cMUT cells would have a vacuum. Many insulating inorganic materials have high dielectric strength, which would help to insulate the cMUT cells from the external environment.

Yet another aspect of the invention is the manufacture of a cMUT device wherein the transducer elements are electrically isolated from each other. In accordance with one embodiment of the invention, electrical isolation can be accomplished by selective ion implantation. Since electrical coupling is governed by the flow of electromagnetic energy, principally the flow of electrons, the coupling can be minimized by modifying electrical conduction in the substrate. More precisely, certain regions in the substrate lying between transducer elements can be doped with ions that change the semiconducting properties of the substrate. By selectively implanting dopants in the regions between the elements, one can form junctions, like back-to-back pn junction diodes, or near-insulating regions that would inhibit electrical crosstalk. In accordance with this approach, no material is removed but the electrical characteristics are altered in selected areas. This process could be done before, during or after the formation of the cMUT cells. If the ion implantation conditions dictate a higher temperature than the temperatures that will prevail during micromachining of the cMUT cells, then one may choose to perform ion implantation before micromachining.

Alternatively, a primarily non-conductive substrate could be used for cMUT fabrication where the bottom electrode would be either deposited metal or selectively doped regions under the cMUT. In this case, it may be desirable to ground the regions between each element by selectively doping these regions and electrically grounding them. Another method of grounding the regions between elements that are separated with isolation trenches (as previously described) would be to coat a surface (e.g., the walls) of the trenches with an electrically conductive material, such as aluminum or an aluminum-silicon alloy, and then connect this metal to ground to electrically isolate one element from the next. Either method would allow stray charges to be conducted to ground rather than to neighboring elements.

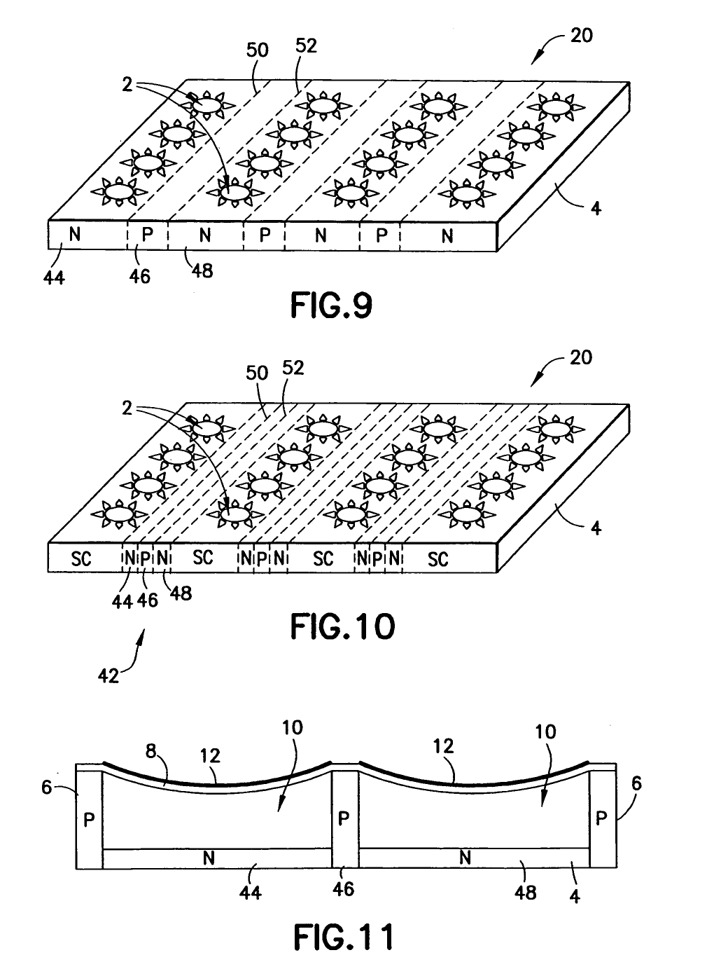

A pn junction diode comprises two volumes of doped semiconductive material that adjoin along a plane, which plane constitutes the junction. The material in one zone is n-type semiconductive material, while the material in the other zone is p-type material. In other words, the semiconductive material is doped differently on either side of the junction. The pn junction diode conducts in one direction but not the other. By placing two pn junction diodes back to back, a device can be formed that does not conduct in either direction. By extending the length of such a pair of back-to-back pn junction diodes, a long barrier to the flow of electrical current can be formed. FIGS. 9 and 10 show two examples of such electrical isolation devices wherein the substrate 4 has been doped to form back-to-back diodes of npn type. In both cases the back-to-back diode is fabricated by implanting doping agents to the required depth in the substrate material.

In the embodiment shown in FIG. 9, the transducer elements (each element comprising a plurality of cMUT cells 2) are built on respective areas 44 and 48 made of n-type semiconductive material, while p-dopants are ion implanted in the areas 46 between the transducer elements. Each area made of n-type semiconductive material serves as a bottom electrode for the transducer element built thereon. Each p-type area is flanked on both sides by respective n-type areas to form respective np junctions 50 and 52. Alternatively, the transducer elements could be built on p-type material, the p-type areas being interleaved with ion-implanted n-type areas between the transducer elements.

In the embodiment shown in FIG. 10, the transducer elements are built on respective areas made of semiconductive or electrically non-conductive (such as undoped poly silicon) material that is neither p-type nor n-type, while in each area located between adjacent transducer elements, n-dopants are ion implanted in the areas 44 and 48, while p-dopants are ion implanted in the area 46 between the areas 44 and 48. Again, each p-type area is flanked on both sides by respective n-type areas to form respective np junctions 50 and 52. Alternatively, instead of npn junctions, pnp junctions could be implanted in the areas between transducer elements.

Thus, neighboring transducer elements can be electrically isolated from each other by placing a barrier of the type shown in FIG. 9 or 10 in the unoccupied space between the neighboring transducer elements.

FIG. 11 shows a cross-sectional view of two transducer elements that share a common wall 46 made of p-type material in accordance with a further embodiment of the invention. It should be appreciated that additional transducer elements are not shown for the sake of economy, but each pair of adjacent transducer elements would share a common wall made of p-type material. The bottom electrodes of the respective elements consist of respective areas 44 and 46 of n-type material. The areas between adjacent areas of n-type material are occupied by the p-type material, which projects upward to form the common walls. The walls of p-type material support the membranes 8, which are suspended above the respective cavities 10 of the individual CMUT cells making up the transducer elements. The cMUT cells of a particular transducer element will preferably share a common bottom electrode made of n-type material.

In the embodiments wherein an acoustic backing layer is placed behind the substrate, the acoustic backing material should have a composition that is acoustically matched to the cMUT substrate, to prevent reflection of the acoustic energy back into the device. In the case where the substrate 4 is made of silicon, one example of a suitable backing material comprises a mixture of 96.3% (by mass) tungsten (of which 85% was 10 micron and 15% was 1 micron particle size) and 3.67% polyvinyl chloride (PVC) powders, as disclosed in U.S. patent application Ser. No. 10/248,022 entitled “Backing Material for Micromachined Ultrasonic Transducer Devices”. Tungsten-vinyl composites are also discussed in a paper by Lees, Gilmore, and Kranz, “Acoustic Properties of Tungsten-Vinyl Composites,” IEEE Transactions on Sonics and Ultrasonics, Vol. SU-20, No. 1, Jan. 1972, pp. 1-2. The person skilled in the art will recognize that the composition of the acoustic backing material can be varied from the examples given above.

Furthermore, the embodiment depicted in FIG. 3 involves placing a flexible interconnect circuit on top of the cMUT array. Another possible means of interconnecting the array is to bring the connections through the backing via wires or traces embedded in the backing material. These connections can then be brought to the surface of the cMUT device by means of through-wafer vias or wrap-around connections. In accordance with a further variation, a flex circuit can be disposed underneath the substrate, and then through-wafer vias or wrap-around connections can be used to bring the signals to the top of the cMUT device. In accordance with a further variation, the cMUT substrate can be connected to a second substrate that provides electrical functions separate from or related to ultrasound transduction such as impedance matching, multiplexing, switching, and transmit and receive beamformation. An acoustic backing layer may be placed between these substrates. In this embodiment, the electrical connections from the cMUT cell electrodes to the electronics on the second substrate can be passed through vias formed in the substrates and the acoustic backing layer.

While the invention has been described with reference to preferred embodiments, it will be understood by those skilled in the art that various changes may be made and equivalents may be substituted for elements thereof without departing from the scope of the invention. In addition, many modifications may be made to adapt a particular situation to the teachings of the invention without departing from the essential scope thereof. Therefore it is intended that the invention not be limited to the particular embodiment disclosed as the best mode contemplated for carrying out this invention, but that the invention will include all embodiments falling within the scope of the appended claims.

As used in the claims, the term “ultrasonic transducer”0 encompasses capacitive and piezoelectric ultrasonic transducers. As used in the claims, the phrase “micromachining a substrate” should be construed to encompass both surface and/or bulk micromachining.

1. A sensor device comprising:
a multiplicity of sensor elements arranged at a front surface of a substrate, each of said sensor elements being in contact with material of said substrate; and
a multiplicity of barriers arranged in said material of said substrate to reduce the coupling of a form of energy between any of said sensor elements, each barrier posing an obstacle to the propagation of said form of energy impinging thereon.

2. The device as recited in claim 1, wherein said barriers are located in areas between neighboring sensor elements.

3. The device as recited in claim 1, wherein said sensor elements are arranged in a row with spacing between neighboring sensor elements, and said barriers are interleaved with said sensor elements, each pair of neighboring sensor elements having a respective barrier therebetween.

4. The device as recited in claim 1, wherein said sensor elements are arranged in a two-dimensional array with spacing between neighboring sensor elements, and said barriers form an interconnected network that defines a multiplicity of bounded areas, each bounded area being occupied by a respective sensor element.

5. The device as recited in claim 1, wherein each of said sensor elements comprises a respective multiplicity of ULTRASONIC TRANSDUCER cells electrically connected together.

6. The device as recited in claim 1, wherein each of said barriers comprises a respective trench.

7. The device as recited in claim 6, wherein each of said trenches starts at said front surface of said substrate and has a depth less than a thickness of said substrate.

8. The device as recited in claim 6, wherein each of said trenches starts at a rear surface of said substrate and has a depth less than a thickness of said substrate.

9. The device as recited in claim 6, wherein each of said sensor elements comprises a respective ultrasonic transducer element, and said trenches are filled with acoustically attenuative material.

10. The device as recited in claim 6, wherein each of said sensor elements comprises a respective ultrasonic transducer element, further comprising a body of acoustically attenuative material that supports said substrate.

11. The device as recited in claim 6, wherein said trenches and adjoining portions of said substrate are coated with a thin layer of insulating material.

12. The device as recited in claim 6, wherein a surface of each of said trenches is coated with an electrically conductive material that is grounded to electrically isolate one sensor element from the next.

13. The device as recited in claim 1, wherein each of said barriers comprises a respective volume of said material of said substrate that has doping agents implanted therein, said doped material having the ability to substantially prevent the flow of electric current therethrough.

14. The device as recited in claim 13, wherein each of said implanted volumes comprises a conductive region that is grounded to prevent charge transfer from one element to the next.

15. The device as recited in claim 13, wherein each of said implanted volumes comprises a respective semiconductive junction.

16. The device as recited in claim 13, wherein each of said volumes comprises a respective pair of back-to-back pn junction diodes.

17. The device as recited in claim 13, wherein each of said implanted volumes comprises a respective near-insulating region.

18. A method of manufacturing a sensor device comprising the following steps:
micromachining an array of sensor elements in or on a substrate; and
forming a multiplicity of barriers in said material of said substrate to reduce the coupling of a form of energy between any of said sensor elements, each barrier posing an obstacle to the propagation of said form of energy impinging thereon.

19. The method as recited in claim 18, wherein said barriers are located in areas between neighboring sensor elements.

20. The method as recited in claim 18, wherein said sensor elements are arranged in a row with spacing between neighboring sensor elements, and said barriers are interleaved with said sensor elements, each pair of neighboring sensor elements having a respective barrier therebetween.

21. The method as recited in claim 18, wherein said sensor elements are arranged in a two-dimensional array with spacing between neighboring sensor elements, and said barriers form an interconnected network that defines a multiplicity of bounded areas, each bounded area being occupied by a respective sensor element.

22. The method as recited in claim 18, wherein said barriers are trenches.

23. The method as recited in claim 22, further comprising the step of filling said trenches with acoustically attenuative material.

24. The method as recited in claim 22, wherein said trenches are formed by dicing, laser cutting or etching.

25. The method as recited in claim 22, wherein each of said sensor elements comprises a respective ultrasonic transducer element, further comprising the step of attaching a body of acoustically attenuative material to a rear face of said substrate.

26. The method as recited in claim 25, wherein said trenches are formed by dicing completely through the thickness of said substrate and into said body of acoustically attenuative material.

27. The method as recited in claim 22, further comprising the step of coating said trenches and adjoining portions of said substrate with a thin layer of electrically insulating material.

28. The method as recited in claim 22, further comprising the steps of coating at least a portion of each trench with an electrically conductive material and then connecting said electrically conductive material to ground in order to electrically isolate one sensor element from the next.

29. The method as recited in claim 18, wherein said forming step comprises implanting doping agents in respective volumes of said material of said substrate, said doped material having the ability to substantially prevent the flow of electric current therethrough.

30. The method as recited in claim 18, wherein said forming step comprises implanting doping agents in respective volumes of said material of said substrate, said doped material having the ability to substantially transfer charge to ground, preventing the flow of electric current from one sensor element to the next.

31. The method as recited in claim 29, wherein said doping agents are implanted in a pattern that forms a respective semiconductive junction for each barrier.

32. The method as recited in claim 29, wherein said doping agents are implanted in a pattern that forms a respective pair of back-to-back pn junction diodes for each barrier.

33. The method as recited in claim 29, wherein said doping agents are implanted in a pattern that forms a respective near-insulating region for each barrier.

34. The method as recited in claim 18, wherein said micromachining step comprises micromachining a multiplicity of ultrasonic transducer cells in or on said substrate, further comprising the step of electrically connecting said ultrasonic transducer cells into groups that form respective sensor elements.

35. An ultrasonic transducer device comprising:
a multiplicity of ultrasonic transducer elements arranged at a front surface of a substrate, each of said transducer elements comprising a respective group of ultrasonic transducer cells electrically connected together and acoustically coupled to said substrate; and
a multiplicity of trenches in said material of said substrate, said trenches being disposed in areas between said transducer elements, and said trenches obstructing the propagation of acoustic wave energy therethrough.

36. The device as recited in claim 35, wherein said trenches are filled with acoustically attenuative material.

37. The device as recited in claim 35, further comprising a body of acoustically attenuative material acoustically coupled to a rear face of said substrate.

38. The device as recited in claim 35, wherein said trenches and adjoining portions of said substrate are coated with a thin layer of insulating material.

39. The device as recited in claim 35, wherein a surface of each of said trenches is coated with an electrically conductive material that is grounded to electrically isolate one transducer element from the next.

40. A sensor device comprising:
a multiplicity of sensor elements arranged at a front surface of a substrate, each of said sensor elements being in contact with material of said substrate; and
a multiplicity of zones of dopant implantation in said material of said substrate, said zones being disposed in areas between said sensor elements, and said zones obstructing the flow of electric current therethrough.

41. The device as recited in claim 40, wherein each of said zones is doped to transfer charge to ground, preventing the flow of electric current from one sensor element to the next.

42. The device as recited in claim 40, wherein each of said zones comprises a respective semiconductive junction.

43. The device as recited in claim 40, wherein each of said zones comprises a respective pair of back-to-back pn junction diodes.

44. The device as recited in claim 40, wherein each of said zones comprises a respective near-insulating region.

45. A method of manufacturing a sensor device comprising the following steps:
micromachining an array of sensors on one side of a substrate;
attaching said one side or the other side of said substrate to a first supporting structure; and
forming a multiplicity of trenches in said material on the side of said substrate not attached to said supporting structure, wherein said trenches are located in areas between said sensor elements.

46. The method as recited in claim 45, wherein said first supporting structure is a layer of acoustically attenuative material attached to said other side of said substrate.

47. The method as recited in claim 45, wherein said first supporting structure is a layer of wax having a relatively low melting temperature attached to said one side of said substrate.

48. The method as recited in claim 45, further comprising the following steps:
attaching a second supporting structure to the side opposite the side to which said first supporting structure is attached; and
removing said first supporting structure.

49. The method as recited in claim 48, wherein said first supporting structure is a layer of wax having a relatively low melting temperature attached to said one side of said substrate, and said removing step comprises melting said wax.

50. The method as recited in claim 49, wherein said second supporting structure is a layer of acoustically attenuative material.
